(19) United States
(12) Patent Application Publication
(10) Pub. No.: US 2025/0366139 A1
(43) Pub. Date: Nov. 27, 2025

(54) SPACER STRUCTURES IN SEMICONDUCTOR DEVICES

(71) Applicant: Taiwan Semiconductor Manufacturing company, Ltd., Hsinchu (TW)

(72) Inventors: Chien Ning YAO, Hsinchu (TW); Chia-Hao CHANG, Hsinchu city (TW); Shih-Cheng CHEN, Taipei city (TW); Chih-Hao WANG, Baoshan Township (TW); Chia-Chang TSAI, Hsinchu (TW); Kuo-Cheng CHIANG, Hsinchu County (TW); Zhi-Chang LIN, Zhubei City (TW); Jung-Hung CHANG, Yuanlin City (TW); Tsung-Han CHUANG, Tainan City (TW)

(73) Assignee: Taiwan Semiconductor Manufacturing company, Ltd., Hsinchu (TW)

(21) Appl. No.: 19/291,170

(22) Filed: Aug. 5, 2025

Related U.S. Application Data
(63) Continuation of application No. 18/232,986, filed on Aug. 11, 2023.
(60) Provisional application No. 63/488,842, filed on Mar. 7, 2023.

(51) Int. Cl. H10D 64/23; H10D 30/43; H10D 30/67; H10D 62/10; H10D 64/01

(52) U.S. Cl. CPC H10D 64/258; H10D 30/43; H10D 30/6735; H10D 62/121; H10D 64/018; H10D 64/021

(57) ABSTRACT

A semiconductor device and a method of fabricating the semiconductor device are disclosed. The method includes forming a polysilicon structure on a substrate, depositing a first spacer layer on the polysilicon structure, depositing a second spacer layer on the first spacer layer, forming a S/D region on the substrate, removing the second spacer layer, depositing a third spacer layer on the first spacer layer and on the S/D region, depositing an ESL on the third spacer layer, depositing an ILD layer on the etch stop layer, and replacing the polysilicon structure with a gate structure surrounding the nanostructured layer.

### CROSS-REFERENCE TO RELATED APPLICATIONS

This application is a continuation of U.S. patent application Ser. No. 18/232,986, titled “Spacer Structures in Semiconductor Devices,” filed Aug. 11, 2023, which claims the benefit of U.S. Provisional Patent Application No. 63/488,842, titled “Methods of Forming a Semiconductor Structure,” filed Mar. 7, 2023, each of which is incorporated by reference herein in its entirety.

### BACKGROUND

With advances in semiconductor technology, there has been increasing demand for higher storage capacity, faster processing systems, higher performance, and lower costs. To meet these demands, the semiconductor industry continues to scale down the dimensions of semiconductor devices, such as metal oxide semiconductor field effect transistors (MOSFETs), including planar MOSFETs and fin field effect transistors (finFETs). Such scaling down has increased the complexity of semiconductor manufacturing processes.

### BRIEF DESCRIPTION OF THE DRAWINGS

Aspects of this disclosure are best understood from the following detailed description when read with the accompanying figures.

FIG. 1A illustrates an isometric view of a semiconductor device with gate spacer structures, in accordance with some embodiments.

FIGS. 1B-1E illustrate different cross-sectional views of a semiconductor device with gate spacer structures, in accordance with some embodiments.

FIG. 2 is a flow diagram of a method for fabricating a semiconductor device with gate spacer structures, in accordance with some embodiments.

FIGS. 3A-11A and 3B-11B illustrate cross-sectional views of a semiconductor device with gate spacer structures at various stages of its fabrication process, in accordance with some embodiments.

Illustrative embodiments will now be described with reference to the accompanying drawings. In the drawings, like reference numerals generally indicate identical, functionally similar, and/or structurally similar elements.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the process for forming a first feature over a second feature in the description that follows may include embodiments in which the first and second features are formed in direct contact, and may also include embodiments in which additional features may be formed between the first and second features, such that the first and second features may not be in direct contact. As used herein, the formation of a first feature on a second feature means the first feature is formed in direct contact with the second feature. In addition, the present disclosure may repeat reference numerals and/or letters in the various examples. This repetition does not in itself dictate a relationship between the various embodiments and/or configurations discussed.

Spatially relative terms, such as “beneath,” “below,” “lower,” “above,” “upper,” and the like may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

It is noted that references in the specification to “one embodiment,” “an embodiment,” “an example embodiment,” “exemplary,” etc., indicate that the embodiment described may include a particular feature, structure, or characteristic, but every embodiment may not necessarily include the particular feature, structure, or characteristic. Moreover, such phrases do not necessarily refer to the same embodiment. Further, when a particular feature, structure or characteristic is described in connection with an embodiment, it would be within the knowledge of one skilled in the art to effect such feature, structure or characteristic in connection with other embodiments whether or not explicitly described.

It is to be understood that the phraseology or terminology herein is for the purpose of description and not of limitation, such that the terminology or phraseology of the present specification is to be interpreted by those skilled in relevant art(s) in light of the teachings herein.

In some embodiments, the terms “about” and “substantially” can indicate a value of a given quantity that varies within 5-20% of the value (e.g., ±1%, ±2%, ±3%, ±4%, ±5%, ±10%, ±10-15%, ±15˜20% of the value). These values are merely examples and are not intended to be limiting. The terms “about” and “substantially” can refer to a percentage of the values as interpreted by those skilled in relevant art(s) in light of the teachings herein.

The GAA transistor structures may be patterned by any suitable method. For example, the structures may be patterned using one or more photolithography processes, including double-patterning or multi-patterning processes. Double-patterning or multi-patterning processes can combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA transistor structure.

The present disclosure provides example structures of low-k (LK) spacer structures in FETs (e.g., finFETs and GAA FETs) to reduce parasitic capacitance in the FETs and provides methods of forming the spacer structures. In some embodiments, a FET can include gate structures surrounding nanostructured channel regions, source/drain (S/D) regions adjacent to the nanostructured channel regions, and LK spacer structures disposed on sidewalls of the gate structures and on the S/D regions. The LK spacer structures can include an inner spacer layer disposed on the sidewalls of the gate structures and an outer spacer layer disposed on the inner spacer layer and the S/D regions. In some embodiments, the inner spacer layer can include a higher concentration of carbon atoms than that in the outer spacer layer and the outer spacer layer can include a higher concentration of nitrogen atoms than that in the inner spacer layer. In some embodiments, the inner spacer layer can include a carbon-rich dielectric material with a low concentration or zero concentration of nitrogen atoms and the outer spacer layer can include a dielectric nitride and/or an oxygen-rich dielectric material with a low concentration or zero concentration of carbon atoms. Such compositions of the inner and outer spacer layers can form the inner spacer layer with a dielectric constant lower than that of the outer spacer layer. In addition, such compositions can form the inner and outer spacer layers with low dielectric constants less than about 4 to reduce or minimize parasitic capacitance between the gate structures and the S/D regions. Reducing the parasitic capacitance can improve the reliability and performance of the FET compared to FETs without the LK spacer structures.

In some embodiments, (i) the inner spacer layer can include silicon oxycarbide (SiOₓC_{y}) or other suitable dielectric carbide material with a higher concentration of carbon atoms than that in silicon oxycarbon nitride (SiOₓC_{y}N_{z}), silicon carbon nitride (SiCₓN_{y}), or other suitable dielectric nitride material of the outer spacer layer, and (ii) the inner spacer layer can include carbon-rich silicon oxycarbide (SiOₓC_{y}) or other suitable carbon-rich dielectric material with a higher concentration of carbon atoms than that in oxygen-rich silicon oxycarbon nitride (SiOₓC_{y}N_{z}), oxygen-rich silicon carbon nitride (SiCₓN_{y}), or other suitable oxygen-rich dielectric material of the outer spacer layer. As used herein, the terms “carbon-rich dielectric material” and “oxygen-rich dielectric material” refer to dielectric materials with non-stoichiometric compositions. The “carbon-rich dielectric material” has a concentration ratio of carbon to any other chemical element of the dielectric material higher than that of the dielectric materials with a stoichiometric composition. The “oxygen-rich dielectric material” has a concentration ratio of oxygen to any other chemical element of the dielectric material higher than that of the dielectric materials with a stoichiometric composition.

In some embodiments, the formation of the LK spacer structure can include (i) forming the inner spacer layers on the sidewalls of the gate structure, (ii) forming sacrificial spacer layers on the inner spacer layers, (iii) removing the sacrificial spacer layers after forming the S/D regions, and (iv) forming the outer spacer layers on the inner spacer layers and the S/D regions. The use of sacrificial spacer layers can prevent the formation of defects on the inner and outer spacer layers. The defects can be in the form of nodules of S/D material formed on the sacrificial spacer layers during the epitaxial growth process of S/D regions. The removal of the sacrificial spacer layers after the formation of the S/D regions can remove these defects and the subsequently-formed outer spacer layers can be formed free of nodular defects. As a result, the uniformity of layers formed on the outer spacer layers are improved with the use of the sacrificial spacer layers.

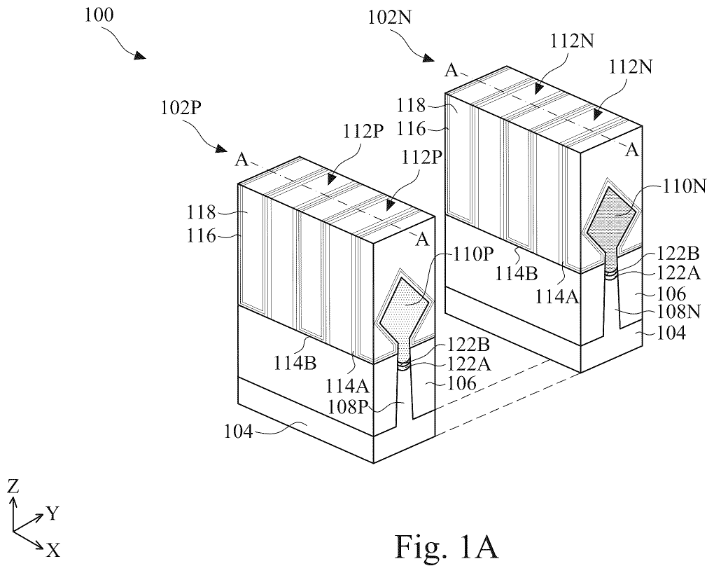

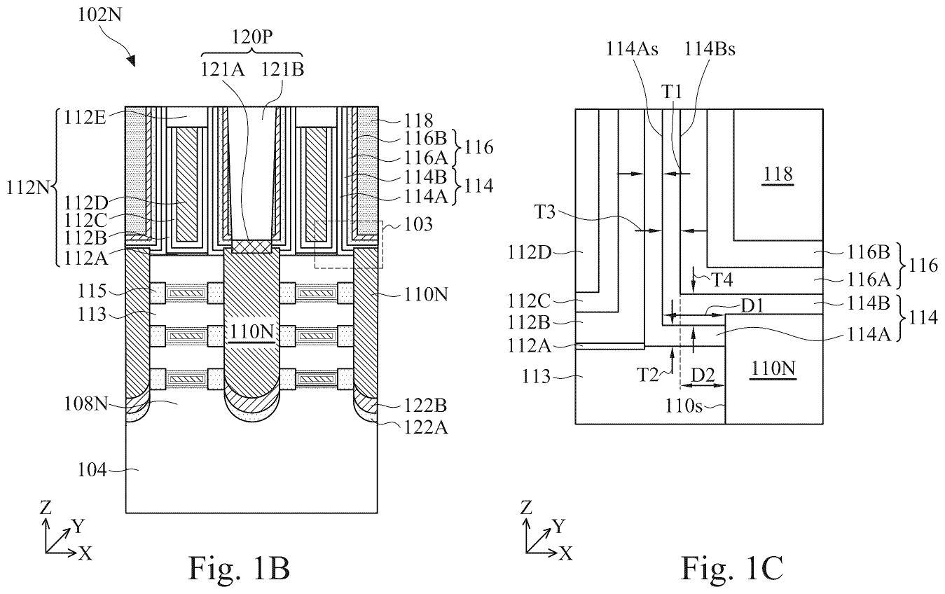

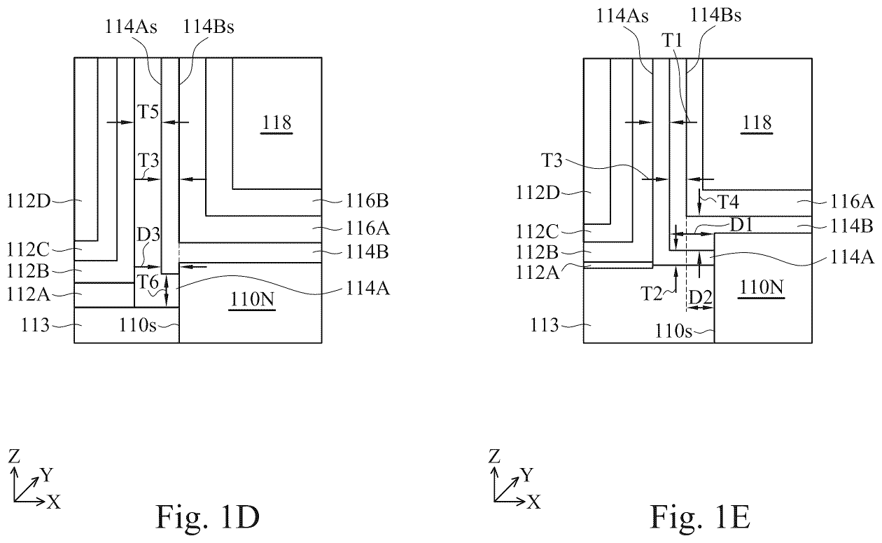

FIG. 1A illustrates an isometric view of a semiconductor device 100 with NFET 102N and PFET 102P, according to some embodiments. FIGS. 1B-1E illustrate different cross-sectional views of NFET 102N along line A-A of FIG. 1A. FIGS. 1B-1E illustrate cross-sectional views of NFET 102N with additional structures that are not shown in FIG. 1A for simplicity. FIGS. 1C-1E illustrate enlarged views of region 103 of FIG. 1B for different cross-sectional views of NFET 102N along line A-A of FIG. 1A. The discussion of the cross-sectional views of NFET 102N in FIGS. 1B-1E applies to cross-sectional views of PFET along line B-B of FIG. 1A, unless mentioned otherwise. The discussion of elements in FIGS. 1A-1E with the same annotations applies to each other, unless mentioned otherwise.

Semiconductor device 100 can be formed on a substrate 104 with NFET 102N and PFET 102P formed on different regions of substrate 104. There may be other FETs and/or structures (e.g., isolation structures) formed between NFET 102N and PFET 102P on substrate 104. In some embodiments, substrate 104 can be a semiconductor material, such as silicon, germanium (Ge), silicon germanium (SiGe), a silicon-on-insulator (SOI) structure, and a combination thereof. Further, substrate 104 can be doped with p-type dopants (e.g., boron, indium, aluminum, or gallium) or n-type dopants (e.g., phosphorus or arsenic). Semiconductor device 100 can further include STI regions 106 disposed on substrate 104. STI regions 106 can include an insulating material, such as silicon oxide (SiO₂), silicon nitride (SiN), silicon oxynitride (SiON), silicon oxycarbide (SiOC), silicon carbon nitride (SiCN), silicon oxycarbon nitride (SiOCN), and silicon germanium oxide (SiGeOₓ).

Referring to FIGS. 1A and 1B, in some embodiments, NFET 102N can include (i) a fin or sheet base 108N disposed on substrate 104, (ii) S/D regions 110N disposed on fin or sheet base 108N, (iii) gate structures 112N disposed on fin or sheet base 108N, (iv) nanostructured channel regions 113 surrounded by gate structures 112N, (v) LK spacer structures 114, (vi) inner spacers 115, (vii) etch stop layers (ESLs) 116, (viii) ILD layers 118 disposed on ESLs 116, (ix) a S/D contact structure 120N disposed on S/D region 110N, and (x) isolation layers 122A and 122B disposed between S/D regions 110N and fin or sheet base 108N.

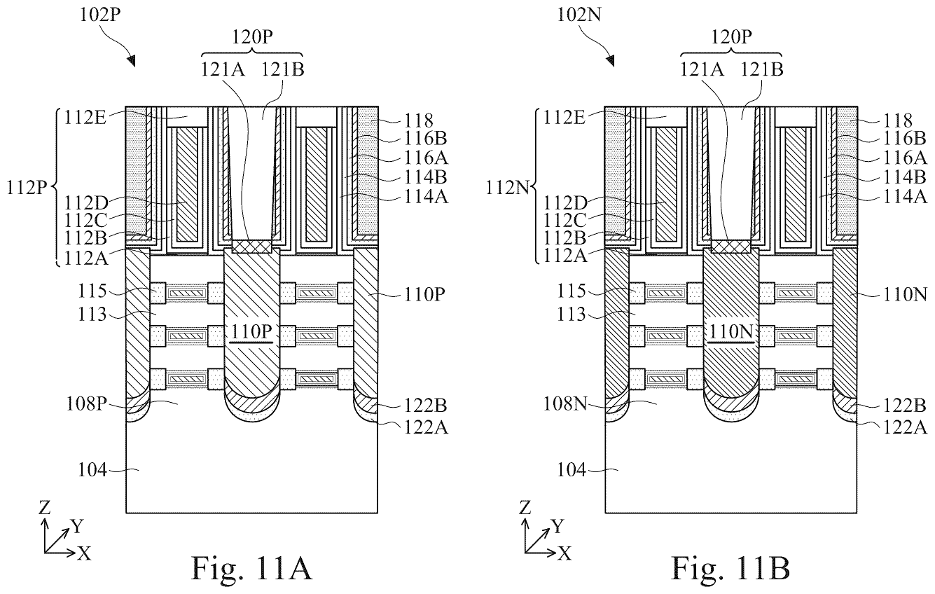

Similarly, Referring to FIG. 1A, in some embodiments, PFET 102P can include (i) a fin or sheet base 108P disposed on substrate 104, (ii) S/D regions 110P disposed on fin or sheet base 108P, (iii) gate structures 112P disposed on fin or sheet base 108P, (iv) nanostructured channel regions 113 (not visible in FIG. 1A, shown in FIG. 11A) surrounded by gate structures 112P, (v) LK spacer structures 114, (vi) inner spacers 115 (not visible in FIG. 1A, shown in FIG. 11A), (vii) ESLs 116, (viii) ILD layers 118 disposed on ESLs 116, (ix) a S/D contact structure 120P (not visible in FIG. 1A, shown in FIG. 11A) disposed on S/D region 110P, and (x) isolation layers 122A and 122B disposed between S/D regions 110P and fin or sheet base 108P. S/D regions 110N and 110P may refer to a source or a drain, individually or collectively dependent upon the context.

Referring to FIGS. 1A and 1B, in some embodiments, fin or sheet base 108N can include a material similar to substrate 104. Fin or sheet base 108N can have elongated sides extending along an X-axis. S/D regions 110N can include an epitaxially-grown semiconductor material, such as Si, and n-type dopants, such as phosphorus and other suitable n-type dopants. S/D regions 110P can include an epitaxially-grown semiconductor material, such as Si and SiGe, and p-type dopants, such as boron and other suitable p-type dopants.

As used herein, the term “nanostructured” defines a structure, layer, and/or region as having a horizontal dimension (e.g., along an X- and/or Y-axis) and/or a vertical dimension (e.g., along a Z-axis) less than about 100 nm, for example about 90 nm, about 50 nm, about 10 nm, or other values less than about 100 nm. In some embodiments, nanostructured channel regions 113 can be in the form of nanosheets, nanowires, nanorods, nanotubes, or other suitable nanostructured shapes. Nanostructured channel regions 113 can include semiconductor materials similar to or different from substrate 104. In some embodiments, nanostructured channel regions 113 can include Si, silicon arsenide (SiAs), silicon phosphide (SiP), silicon carbide (SiC), silicon carbon phosphide (SiCP), silicon germanium (SiGe), silicon germanium boron (SiGeB), germanium boron (GeB), silicon germanium stannum boron (SiGeSnB), a III-V semiconductor compound, or other suitable semiconductor materials. Though rectangular cross-sections of nanostructured channel regions 113 are shown, nanostructured channel regions 113 can have cross-sections of other geometric shapes (e.g., circular, elliptical, triangular, or polygonal).

In some embodiments, the portions of gate structures 112N surrounding nanostructured channel regions 113 can be electrically isolated from adjacent S/D regions 110N by inner spacers 115. Similarly, the portions of gate structures 112P surrounding nanostructured channel regions 113 (shown in FIG. 11A) can be electrically isolated from adjacent S/D regions 110P by inner spacers 115. Inner spacers 115 can include an insulating material, such as SiOₓ, SiN, SiCN, SiOCN, and other suitable insulating materials.

Each of gate structures 112N and 112P can be a multi-layered structure and can surround nanostructured channel regions 113 for which gate structures 112N and 112P can be referred to as “GAA structures.” In some embodiments, each of gate structures 112N can include (i) an interfacial oxide (IL) layer 112A, (ii) a high-k (HK) gate dielectric layer 112B disposed on IL layer 112A, (iii) a work function metal (WFM) layer 112C disposed on HK gate dielectric layer 112B, (iv) a gate metal fill layer 112D disposed on WFM layer 112C and (v) a conductive capping layer 112E disposed on gate metal fill layer 112D.

In some embodiments, IL layer 112A can include SiO₂, SiGeOₓ, or germanium oxide (GeOₓ). In some embodiments, HK gate dielectric layer 112B can include a high-k dielectric material, such as hafnium oxide (HfO₂), titanium oxide (TiO₂), hafnium zirconium oxide (HfZrO), tantalum oxide (Ta₂O₃), hafnium silicate (HfSiO₄), zirconium oxide (ZrO₂), and zirconium silicate (ZrSiO₂). In some embodiments, WFM layer 112C can include titanium aluminum (TiAl), titanium aluminum carbide (TiAlC), tantalum aluminum (TaAl), tantalum aluminum carbide (TaAlC), Al-doped Ti, Al-doped TiN, Al-doped Ta, Al-doped TaN, or other suitable Al-based materials for NFET 102N. In some embodiments, WFM layer 112C can include substantially Al-free (e.g., with no Al) Ti-based or Ta-based nitrides or alloys, such as titanium nitride (TiN), titanium silicon nitride (TiSiN), titanium gold (Ti—Au) alloy, titanium copper (Ti—Cu) alloy, tantalum nitride (TaN), tantalum silicon nitride (TaSiN), tantalum gold (Ta—Au) alloy, and tantalum copper (Ta—Cu) for PFET 102P. In some embodiments, gate metal fill layer 113D can include a suitable conductive material, such as tungsten (W), titanium (Ti), silver (Ag), ruthenium (Ru), molybdenum (Mo), copper (Cu), cobalt (Co), Al, iridium (Ir), nickel (Ni), metal alloys, and a combination thereof.

Conductive capping layer 112E can provide a conductive interface between gate metal fill layer 112D and a gate contact structure (not shown) to electrically connect gate metal fill layer 112D to the gate contact structure without forming the gate contact structure directly on or within gate metal fill layer 112D. The gate contact structure is not formed directly on or within gate metal fill layer 112D to prevent contamination by any of the processing materials used in the formation of the gate contact structure. Contamination of gate metal fill layer 112D can lead to the degradation of device performance. Thus, with the use of conductive capping layer 112E, gate structure 112 can be electrically connected to the gate contact structure without compromising the integrity of gate structure 112.

In some embodiments, conductive capping layer 112E can have a thickness of about 1 nm to about 8 nm for adequately providing a conductive interface between gate metal fill layer 112D and the gate contact structure without compromising the size and manufacturing cost of semiconductor device 100. In some embodiments, the total thickness of conductive capping layer 112E and gate metal fill layer 112D can range from about 10 nm to about 30 nm. In some embodiments, conductive capping layer 112E can include a metallic material, such as W, Ru, Mo, Co, other suitable metallic materials, and a combination thereof. In some embodiments, conductive capping layer 112E can be formed using a precursor gas of tungsten pentachloride (WCl₅) or tungsten hexachloride (WCl₆), and as a result, conductive capping layer 112E can include tungsten with impurities of chlorine atoms. The concentration of chlorine atom impurities can range from about 1 atomic percent to about 10 atomic percent of the total concentration of atoms in each conductive capping layer 112E.

Referring to FIGS. 1A-1C, in some embodiments, gate structures 112N can be electrically isolated from adjacent S/D regions 110N and from S/D contact structure 120N by LK spacer structures 114. In some embodiments, each LK spacer structure 114 can include an LK inner spacer layer 114A and an LK outer spacer layer 114B. LK inner spacer layers 114A can be disposed directly on sidewalls of gate structures 112N and on sidewalls of S/D regions 110N. LK outer spacer layers 114B can be disposed directly on LK inner spacer layers 114A and on sidewalls and top surfaces of S/D regions 110N.

In some embodiments, the dielectric constants (k-value) of LK inner spacer layer 114A and LK outer spacer layer 114B can be less than about 4 (e.g., less than that of SiO₂, less than about 3.9, or about 1 to about 3.8). The low-k values of LK inner spacer layer 114A and LK outer spacer layer 114B can reduce or minimize parasitic capacitance between gate structures 112N and S/D regions 110N, and between gate structures 112N and S/D contact structure 120N. Reducing the parasitic capacitance can improve the reliability and performance of NFET 102 compared to NFETs without LK spacer structures 114.

In some embodiments, LK inner spacer layer 114A can include fluorine dopants and LK outer spacer layer 114B can be undoped. Due to the presence of fluorine dopants, LK inner spacer layer 114A can have a lower dielectric constant than that of LK outer spacer layer 114B. In some embodiments, LK inner spacer layer 114A and LK outer spacer layer 114B can include dielectric materials different from each other and the dielectric materials can have a composition of silicon, oxygen, carbon, and/or nitrogen atoms that can form LK inner spacer layer 114A and LK outer spacer layer 114B with dielectric constants less than about 4. In some embodiments, LK inner spacer layer 114A can include a dielectric material with a higher concentration of carbon atoms than its concentration of nitrogen atoms, while LK outer spacer layer 114B can include a dielectric material with a higher concentration of nitrogen atoms than its concentration of carbon atoms. In some embodiments, LK inner spacer layer 114A can include a dielectric material (e.g., SiOC) with zero concentration of nitrogen atoms, while LK outer spacer layer 114B can include a dielectric material (e.g., SiN, SiON, etc.) with zero concentration of carbon atoms. In some embodiments, LK inner spacer layer 114A can include a carbon-rich dielectric material, while LK outer spacer layer 114B can include a dielectric nitride material or an oxygen-rich dielectric material.

The higher concentration of carbon atoms in LK inner spacer layer 114A can form LK inner spacer layer 114A with a lower dielectric constant than that of LK outer spacer layer 114B. And, the higher concentration of nitrogen atoms or oxygen atoms in LK outer spacer layer 114B can form LK outer spacer layer 114B with a higher etch resistance than that of LK inner spacer layer 114A. In some embodiments, LK outer spacer layer 114B can be formed with a higher etch resistance to protect LK inner spacer layer 114A and gate structures 112N from being etched during subsequent etch processes performed in the formation of S/D contact structure 120N. In addition, LK outer spacer layer 114B can be formed with a higher etch resistance to function as an etch stop layer.

In some embodiments, LK inner spacer layer 114A can include SiOₓC_{y}N_{z} or SiCₓN_{y} with a higher concentration of carbon atoms than nitrogen atoms, while LK outer spacer layer 114B can include SiOₓC_{y}N_{z} or SiCₓN_{y} with a higher concentration of nitrogen atoms than carbon atoms. In some embodiments, LK inner spacer layer 114A can include SiOₓC_{y} or other suitable dielectric carbide material with a higher concentration of carbon atoms than that in SiOₓC_{y}N_{z}, SiCₓN_{y}, or other suitable dielectric nitride material of LK outer spacer layer 114B. In some embodiments, LK inner spacer layer 114B can include SiOₓC_{y}N_{z}, SiCₓN_{y}, silicon oxynitride (SiOₓN_{y}), or other suitable dielectric nitride material with a higher concentration of nitrogen atoms than that in SiOₓC_{y}N_{z}, SiCₓN_{y}, or other suitable dielectric material of LK inner spacer layer 114A. In some embodiments, LK inner spacer layer 114A can include carbon-rich SiOₓC_{y} or other suitable carbon-rich dielectric material, while LK outer spacer layer 114B can include SiOₓC_{y}N_{z}, SiCₓN_{y}, or other suitable dielectric nitride material. In some embodiments, LK inner spacer layer 114A can include carbon-rich SiOₓC_{y} or other suitable carbon-rich dielectric material, while LK outer spacer layer 114B can include oxygen-rich SiOₓC_{y}N_{z}, SiCₓN_{y}, or other suitable oxygen-rich dielectric material. These different compositions can form LK inner spacer layer 114A and LK outer spacer layer 114B with low dielectric constants less than about 4.

The relative dielectric constants of LK inner spacer layer 114A and LK outer spacer layer 114B can depend on their relative thicknesses. In some embodiments, LK inner spacer layer 114A can have a thickness T1 smaller than thickness T3 of LK outer spacer layer 114B, which can result in LK inner spacer layer 114A with a dielectric constant higher than that of LK outer spacer layer 114B. On the other hand, in some embodiments, LK inner spacer layer 114A can have a thickness T5 (shown in FIG. 1D) greater than thickness T3 (shown in FIG. 1D) of LK outer spacer layer 114B, which can result in LK inner spacer layer 114A with a dielectric constant lower than that of LK outer spacer layer 114B.

In some embodiments, LK inner spacer layer 114A and LK outer spacer layer 114B can have L-shaped cross-sectional profiles. In some embodiments, the vertical portion of LK inner spacer layer 114A can have thickness T1 of about 2 nm to about 3 nm and the horizontal portion of LK inner spacer layer 114A can have thickness T2 of about 3 nm to about 4 nm. In some embodiments, the vertical portion of LK outer spacer layer 114B can have thickness T3 of about 4 nm to about 6 nm and the horizontal portion of LK outer spacer layer 114B disposed on LK inner spacer layer 114A can have thickness T4 of about 5 nm to about 7 nm.

In some embodiments, LK inner spacer layer 114A can be separated from adjacent S/D region 110N by a distance D1 (shown in FIG. 1C) or by a distance D3 between sidewall 114As of LK inner spacer layer 114A and sidewall 110s of S/D region 110N. In some embodiments, distance D1 can be about 8 nm to about 10 nm and distance D3 can be about 4 nm to about 6 nm. Within these ranges of thickness T1-T4 and distances D1 and D3, LK inner spacer layer 114A and LK outer spacer layer 114B can adequately isolate gate structures 112N from S/D regions 110N and S/D contact structure 120 while minimizing the parasitic capacitance between them. In some embodiments, sidewall 110s of S/D region 110N can be misaligned and offset by a distance D2 (shown in FIG. 1C) with sidewall 114Bs of LK outer spacer layer 114B when LK inner spacer layer 114A is separated from S/D region 110N by distance D1. On the other hand, in some embodiments, sidewall 110s of S/D region 110N can be aligned (shown in FIG. 1D with a dashed line) with sidewall 114Bs of LK outer spacer layer 114B when LK inner spacer layer 114A is separated from S/D region 110N by distance D3.

In some embodiments, ESL 116 can include an inner ESL 116A disposed on LK outer spacer layer 114B and an outer ESL 116B disposed on ESL 116A. In some embodiments, ESL 116A can have a dielectric constant of about 4 to about 5 and ESL 116B can have a higher dielectric constant of about 6 to about 7. In some embodiments, ESLs 116A and 116B can include a dielectric material, such as lanthanum oxide (LaO), aluminum oxide (Al₂O₃), yttrium oxide (Y₂O₃), tantalum carbon nitride (TaCN), zirconium silicide (ZrSi), SiOCN, SiOC, SiCN, zirconium nitride (ZrN), zirconium aluminum oxide (ZrAlO), TiO₂, Ta₂O₃, ZrO₂, HfO₂, SiN, hafnium silicide (HfSi), aluminum oxynitride (AlON), SiO₂, SiC, SiN, and zinc oxide (ZnO). In some embodiments, ESLs 116A can include SiOCN with a dielectric constant of about 5, while ESL 116B can include SiN with a dielectric constant of about 6. In some embodiments, ESL 116 can include a single layer of ESL 116A, as shown in FIG. 1E, instead of dual layers of ESL 116A and 116B. In some embodiments, ILD layer 118 can be disposed on ESL 116B, as shown in FIG. 1C or can be disposed on ESL 116A, as shown in FIG. 1E. In some embodiments, ILD layer 118 can include an insulating material, such as SiO₂, SiN, SiON, SiCN, SiOCN, and SiGeOₓ.

In some embodiments, S/D contact structure 122 can include (i) a silicide layer 121A, and (ii) a contact plug 121B disposed on silicide layer 121A. Silicide layer 121A can be disposed partly in S/D region 110N and partly in LK outer spacer layer 114B, as shown in FIG. 1B. Contact plug 121B can be disposed on silicide layer 121A. In some embodiments, sidewalls of contact plug 121B can be in contact with LK outer spacer layers 114B, inner ESLs 116A, outer ESLs 116B, and ILD layer 118, as shown in FIG. 1B. In some embodiments, silicide layers 121A in NFET 102N can include titanium silicide (TiₓSi_{y}), tantalum silicide (TaₓSi_{y}), molybdenum (MoₓSi_{y}), zirconium silicide (ZrₓSi_{y}), hafnium silicide (HfₓSi_{y}), scandium silicide (ScₓSi_{y}), yttrium silicide (YₓSi_{y}), terbium silicide (TbₓSi_{y}), lutetium silicide (LuₓSi_{y}), erbium silicide (ErₓSi_{y}), ytterbium silicide (YbₓSi_{y}), europium silicide (EuₓSi_{y}), thorium silicide (ThₓSi_{y}), other suitable metal silicide materials, or a combination thereof. In some embodiments, silicide layers 121A in PFET 102P (shown in FIG. 11A) can include nickel silicide (NiₓSi_{y}), cobalt silicide (CoₓSi_{y}), manganese silicide (MnₓSi_{y}), tungsten silicide (WₓSi_{y}), iron silicide (FeₓSi_{y}), rhodium silicide (RhₓSi_{y}), palladium silicide (PdₓSi_{y}), ruthenium silicide (RuₓSi_{y}), platinum silicide (PtₓSi_{y}), iridium silicide (IrₓSi_{y}), osmium silicide (OsₓSi_{y}), other suitable metal silicide materials, or a combination thereof.

In some embodiments, contact plug 121B can include conductive materials with low resistivity (e.g., resistivity of about 50 μΩ-cm, about 40 μΩ-cm, about 30 μΩ-cm, about 20 μΩ-cm, or about 10 μΩ-cm), such as Co, W, Ru, Al, Mo, iridium (Ir), nickel (Ni), Osmium (Os), rhodium (Rh), other suitable conductive materials with low resistivity, and a combination thereof.

In some embodiments, isolation layers 122A and 122B can be configured to electrically isolate S/D regions 110N from underlying fin or sheet base 108N and S/D regions 110P from underlying fin or sheet base 108P. The presence of isolation layers 122A and 122B can prevent or minimize current leakage between adjacent S/D regions 110N on same fin or sheet base 108N and between adjacent S/D regions 110P on same fin or sheet base 108P. In some embodiments, isolation layers 122A and 122B can include dielectric materials different from each other. In some embodiments, isolation layers 122A can include the same dielectric material of inner spacers 115. In some embodiments, isolation layers 122B can include a dielectric material, such as SiO₂, SIN, SiCN, SiOCN, and other suitable dielectric material.

In some embodiments, NFET 102 and PFET 102P can be finFETs, instead of GAA FETs, and can have fin structures (not shown) instead of nanostructured channel regions 113 and fin bases 108N-108P. Unlike GAA FET, finFET can have gate structures 112N and 112P disposed on fin structures, which can have fin regions to function as channel regions.

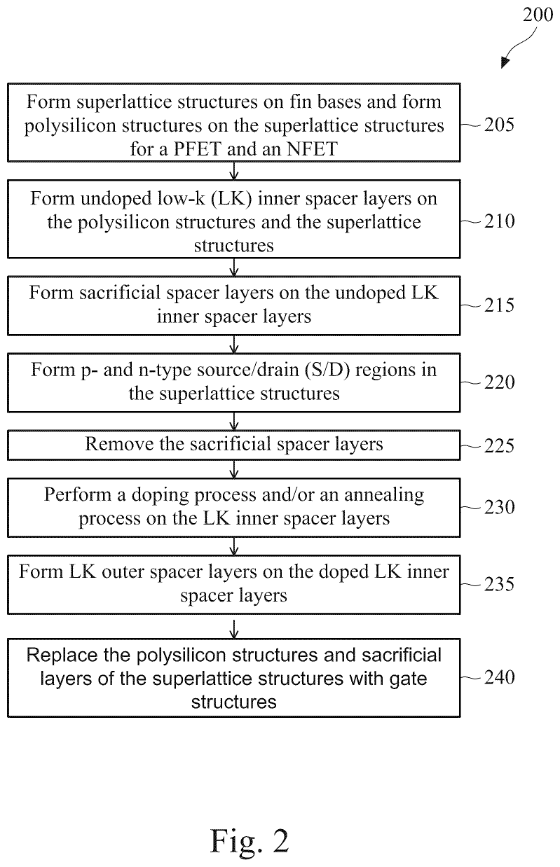

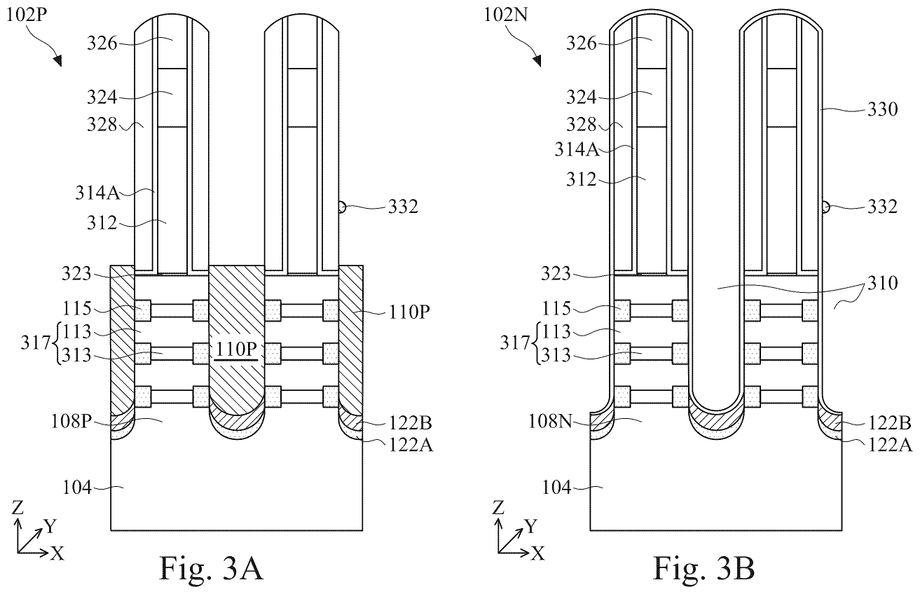

FIG. 2 is a flow diagram of an example method 200 for fabricating semiconductor device 100 with NFET 102N and PFET 102P as described above with reference to FIG. 1A-1C, according to some embodiments. For illustrative purposes, the operations illustrated in FIG. 2 will be described with reference to the example fabrication process for fabricating semiconductor device 100 as illustrated in FIGS. 3A-11A and 3B-11B. FIGS. 3A-11A are cross-sectional views of NFET 102N along line A-A of FIG. 1A at various stages of fabrication, according to some embodiments. FIGS. 3B-11B are cross-sectional views of PFET 102P along line B-B of FIG. 1A at various stages of fabrication, according to some embodiments. Operations can be performed in a different order or not performed depending on specific applications. It should be noted that method 200 may not produce a complete semiconductor device 100. Accordingly, it is understood that additional processes can be provided before, during, and after method 200, and that some other processes may only be briefly described herein. The discussion of elements in FIGS. 1A-1E, 3A-11A, and 3B-11B with the same annotations applies to each other, unless mentioned otherwise.

Referring to FIG. 2, in operation 205, superlattice structures are formed on fin bases, and polysilicon structures are formed on the superlattice structures for PFET and NFET. For example, as described with reference to FIGS. 3A and 3B, superlattice structures 317 are formed on fin bases 108P and 108N, and polysilicon structures 312 are formed on superlattice structures 317. In some embodiments, hard mask layers 324 and 326 can be formed during the formation of polysilicon structures 312. Superlattice structures 317 can include nanostructured layers 113 and 313 arranged in an alternating configuration. In some embodiments, nanostructured layers 113 and 313 include materials different from each other. Nanostructured layers 313 are also referred to as “sacrificial layers 313.” During subsequent processing, polysilicon structures 312 and sacrificial layers 313 can be replaced in a gate replacement process to form gate structures 112P and 112N. In some embodiments, thermal oxide layers 323 can be formed on superlattice structures 317 prior to the formation of polysilicon structures 312.

Referring to FIG. 2, in operation 210, undoped LK inner spacer layers are formed on the polysilicon structures and the superlattice structures. For example, as described with reference to FIGS. 3A and 3B, undoped LK inner spacer layers 314A are formed on sidewalls of polysilicon structures 312 and thermal oxide layers 323 and on top surfaces of superlattice structure 317. In some embodiments, undoped LK inner spacer layers 314A can be formed in a chemical vapor deposition (CVD) process, an atomic layer deposition (ALD) process, or other suitable dielectric material deposition process.

In some embodiments, the formation of undoped LK inner spacer layers 314A can include depositing a layer of (i) dielectric material with a composition of silicon, oxygen, carbon, and/or nitrogen atoms, which has a higher concentration of carbon atoms than its concentration of nitrogen atoms, (ii) dielectric material (e.g., SiOC) with zero concentration of nitrogen atoms, (iii) carbon-rich dielectric material, (iv) SiOₓC_{y}N_{z} or SiCₓN_{y} with a higher concentration of carbon atoms than nitrogen atoms, and/or (iv) carbon-rich SiOₓC_{y} or other suitable carbon-rich dielectric material that achieve a dielectric constant less than about 4.

Referring to FIG. 2, in operation 215, sacrificial spacer layers are formed on the undoped LK inner spacer layers. For example, as described with reference to FIGS. 3A and 3B, sacrificial spacer layers 328 are formed on undoped LK inner spacer layers 314A. In some embodiments, sacrificial spacer layers 328 can be formed in a CVD process, an ALD process, or other suitable dielectric material deposition process. In some embodiments, the formation of sacrificial spacer layers 328 can include depositing a layer of dielectric material, such as SiO₂, SiN, SiON, SiCN, and SiOCN.

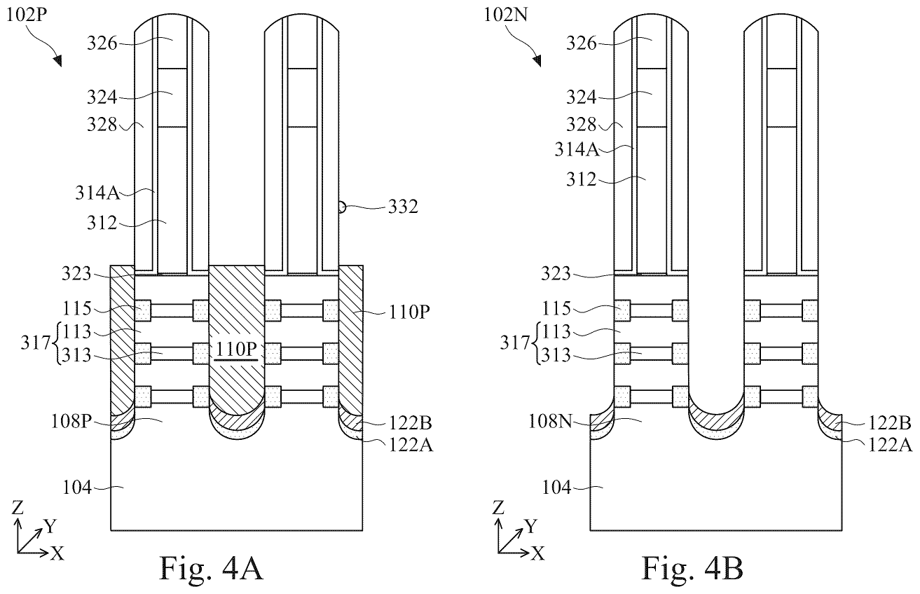

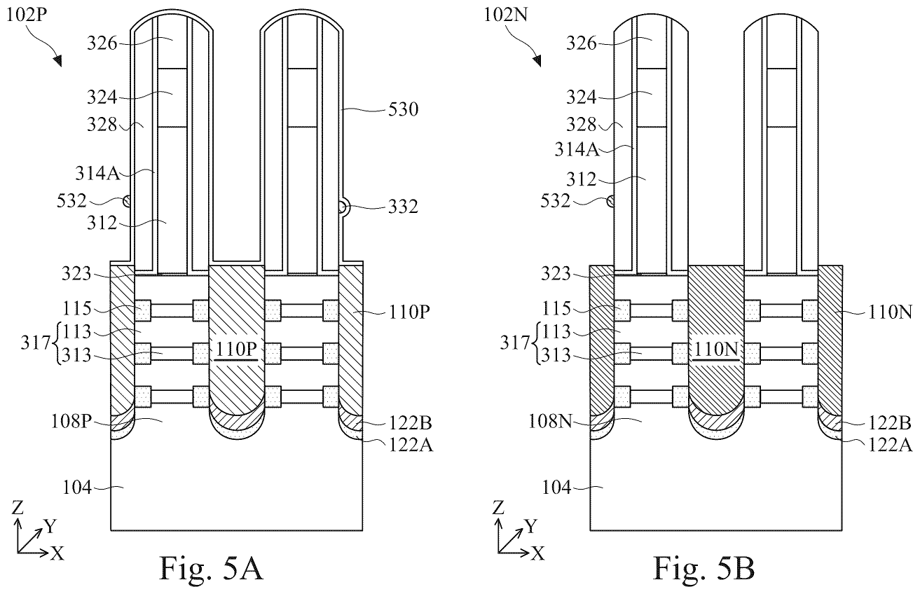

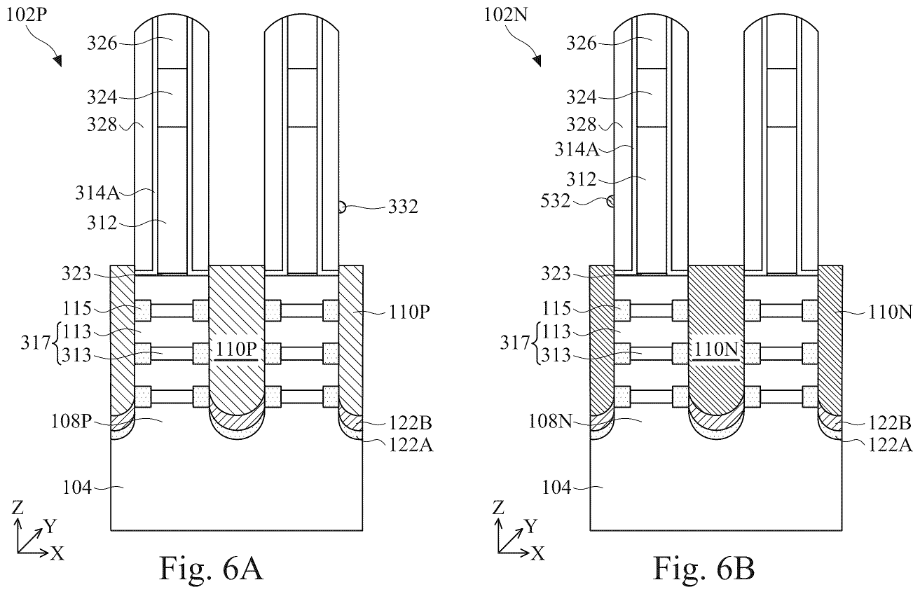

Referring to FIG. 2, in operation 220, p-type and n-type S/D regions are formed in the superlattice structures. For example, as described with reference to FIGS. 3A-6A and 3B-6B, S/D regions 110P and 110N are formed in superlattice structures 317 and on fin bases 108P and 108N. The formation of S/D regions 110P and 110N can include sequential operations of (i) forming S/D openings 310 (not shown in PFET 102P) in superlattice structures 317, as shown in FIG. 3B, (ii) depositing a hard mask layer (not shown) on PFET 102P and NFET 102N (iii) removing the portion of hard mask layer on PFET 102P to form a hard mask layer 330 on NFET 102N, as shown in FIG. 3B, (iv) epitaxially growing semiconductor material in S/D openings of PFET 102P, as shown in FIG. 3A, (v) removing hard mask layer 330 to form the structure of FIG. 4B, (vi) depositing a hard mask layer (not shown) on the structures of FIGS. 4A and 4B, (vii) removing the portion of hard mask layer on NFET 102N to form a hard mask layer 530 on PFET 102P, as shown in FIG. 5A, (viii) epitaxially growing semiconductor material in S/D openings of NFET 102N, as shown in FIG. 5B, and (ix) removing hard mask layer 530 to form the structure of FIG. 6A.

In some embodiments, defects in the form of nodules 332 can be formed on sacrificial spacer layers 328 and hard mask layer 330 during the formation of S/D regions 110P, as shown in FIGS. 3A and 3B. These nodules 332 can be a result of unintentional deposition of semiconductor material on sacrificial spacer layers 328 and hard mask layer 330 during the epitaxial growth of the semiconductor material in S/D openings of PFET 102P. Similarly, in some embodiments, defects in the form of nodules 532 can be formed on sacrificial spacer layers 328 and hard mask layer 530 during the epitaxial growth of semiconductor material in S/D openings of NFET 102N, as shown in FIGS. 5A and 5B. These nodules 332 and 532 can be removed with the removal of sacrificial spacer layers 328, as described below.

In some embodiments, inner spacers 115 and isolation layers 122A and 122B can be formed after the formation of S/D openings 310 in PFET 102P and NFET 102N, and prior to the formation of hard mask layer on PFET 102P and NFET 102N in operation (ii) described above with reference to FIGS. 3A and 3B.

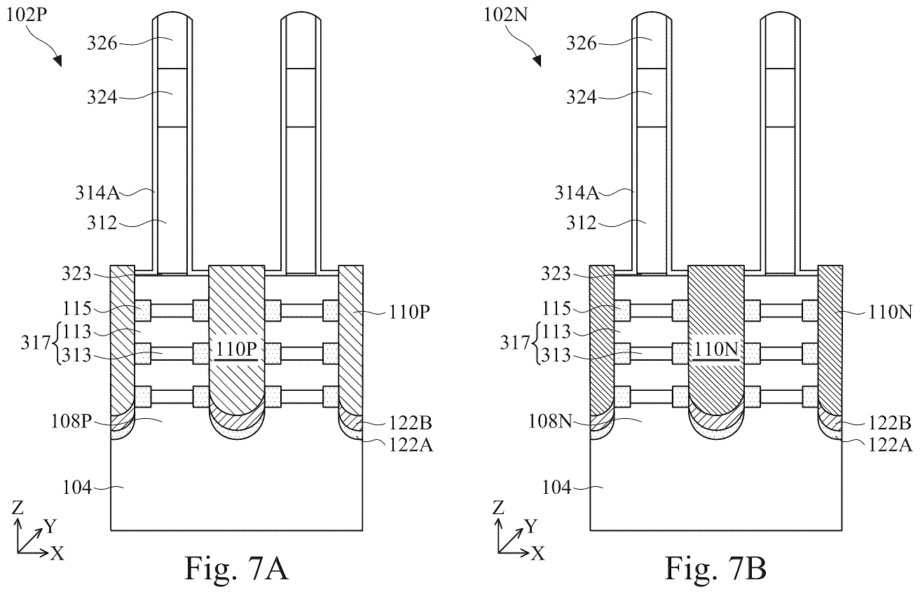

Referring to FIG. 2, in operation 225, sacrificial spacer layers are removed. For example, as described with reference to FIGS. 7A and 7B, sacrificial spacer layers 328 are removed from the structures of FIGS. 6A and 6B to form the structures of FIGS. 7A and 7B. With the removal of sacrificial spacer layers 328, nodules 332 and 532 can also be removed. As a result, the formation of defects on undoped LK inner spacer layers 314A can be prevented and the uniformity of subsequently-formed layers on undoped LK inner spacer layers 314A can be improved.

In some embodiments, the removal of sacrificial spacer layers 328 can include performing a three-stage wet etch process on the structures of FIGS. 6A and 6B. The three-stage process can include sequential operations of (i) exposing the structures of FIGS. 6A and 6B to a high temperature sulfuric peroxide mixture (HTSPM) (also referred to as an “oxidizing solution”) to oxidize sacrificial spacer layers 328, (ii) exposing the structures of FIGS. 6A and 6B with oxidized sacrificial spacer layers 328 (not shown) to a solution of dilute hydrofluoric acid (DHF) to etch oxidized sacrificial spacer layers 328 and form the structures of FIGS. 7A and 7B, and (iii) exposing the structures of FIGS. 7A and 7B to a mixture of ammonia hydroxide (NH₄OH), hydrogen peroxide (H₂O₂), and water (“SC1 solution”) to remove any residues of sacrificial spacer layers 328 and/or contaminants from the exposed surfaces of undoped LK inner spacer layers 314A and S/D regions 110P and 110N. In some embodiments, the thickness of undoped LK inner spacer layers 314A in FIGS. 7A and 7B can be thinner than that in FIGS. 6A and 6B due to portions of undoped LK inner spacer layers 314A being etched during the three-stage wet etch process.

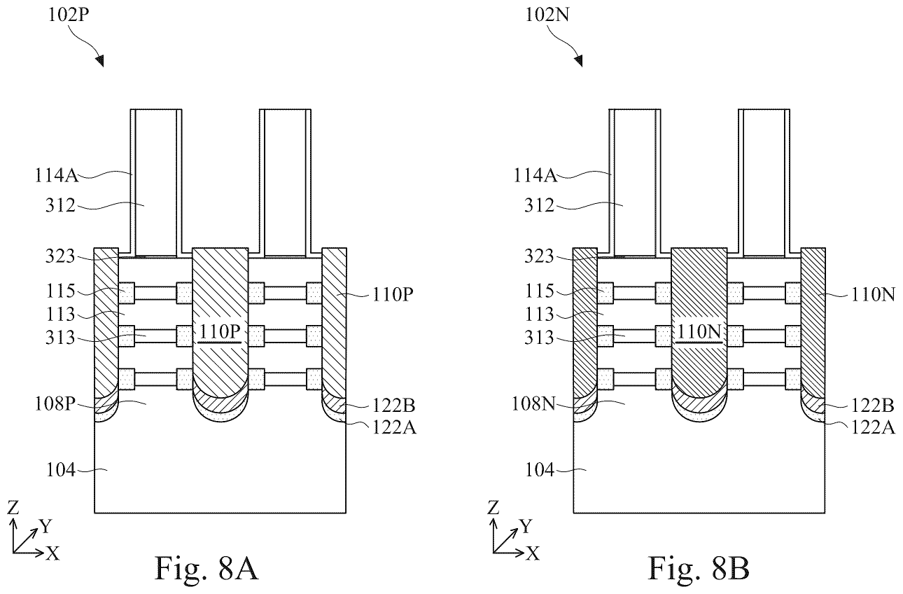

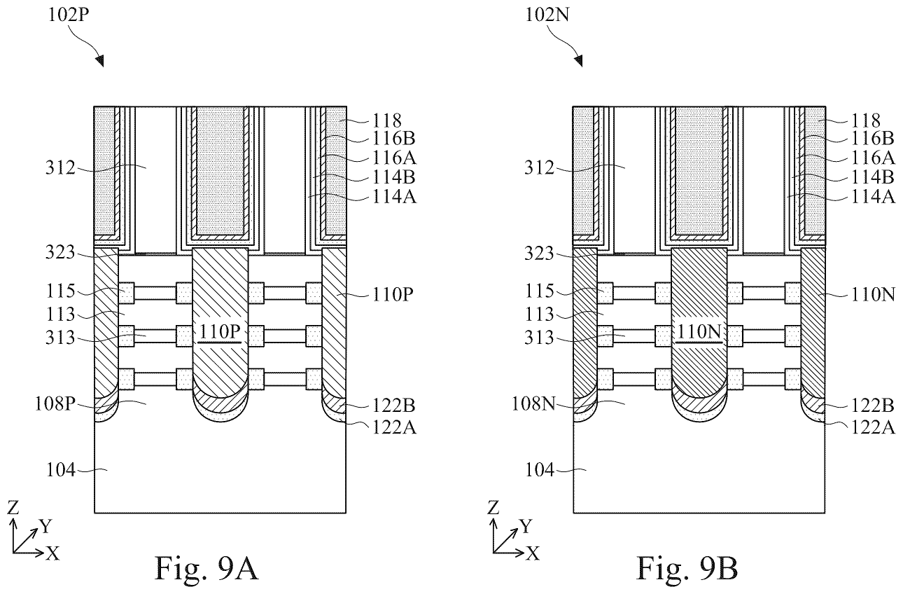

Referring to FIG. 2, in operation 230, a doping process and/or an annealing process are performed on the undoped LK inner spacer layers. For example, as described with reference to FIGS. 8A and 8B, LK inner spacers 114A with fluorine dopants can be formed. In some embodiments, a doping process with fluorine dopants can be performed on the structures of FIGS. 7A and 7B after the three-stage wet etch process of operation 225. The fluorine dopants can be added to further lower the dielectric constant of LK inner spacer layers 114A compared to undoped LK inner spacer layers 314A. In some embodiments, the doping process can be followed by an annealing process at a temperature of about 400° C. to about 600° C. to densify LK inner spacer layers 114A and increase the etch resistance of LK inner spacer layers 114A. In some embodiments, the doping process and/or the anneal process may not be performed. In some embodiments, operation 225 can be followed by operation 235 without performing operation 230 on the structures of FIGS. 7A and 7B, in which case undoped LK inner spacer layers 314A can be LK inner spacer layers 114A of FIGS. 9A and 9B.

Referring to FIG. 2, in operation 235, LK outer spacer layers are formed on the LK inner spacer layers. For example, as described with reference to FIGS. 9A and 9B, LK outer spacer layers 114B are formed on LK inner spacer layers 114A. In some embodiments, LK outer spacer layers 114B can be formed in a CVD process, an ALD process, or other suitable dielectric material deposition process. In some embodiments, the formation of LK outer spacer layers 114B can include depositing a layer of (i) dielectric material with a composition of silicon, oxygen, carbon, and/or nitrogen atoms, which has a higher concentration of nitrogen atoms than its concentration of carbon atoms, (ii) dielectric material (e.g., SiN, SiON, etc.) with zero concentration of carbon atoms, (iii) dielectric nitride material or an oxygen-rich dielectric material, (iv) SiOₓC_{y}N_{z} or SiCₓN_{y} with a higher concentration of nitrogen atoms than carbon atoms, and/or (v) oxygen-rich SiOₓC_{y}N_{z}, SiCₓN_{y}, or other suitable oxygen-rich dielectric material that achieve a dielectric constant less than about 4. The formation of LK outer spacer layers 114B can be followed by the formation of ESLs 116 and ILD layers 118, as shown in FIGS. 9A and 9B.

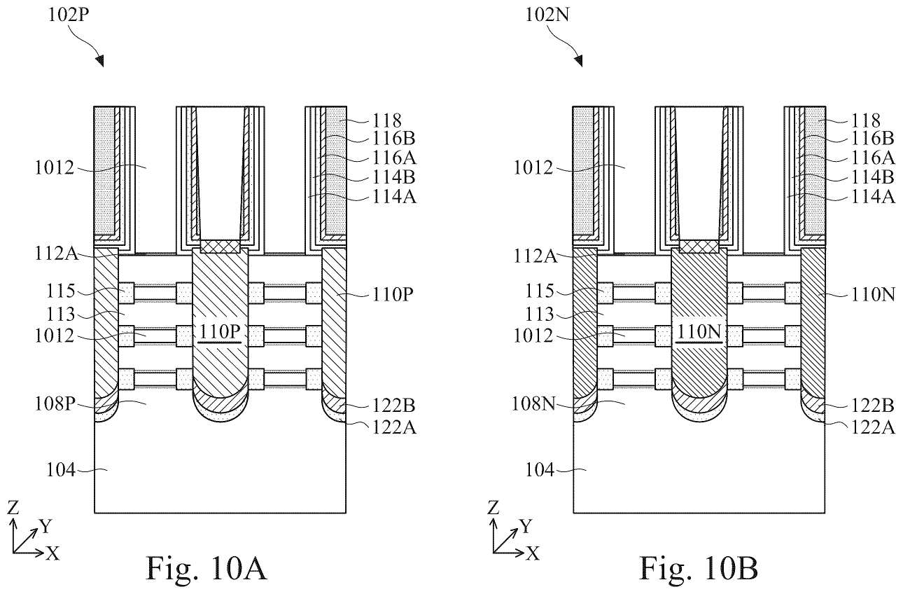

Referring to FIG. 2, in operation 240, the polysilicon structures and sacrificial layers of the superlattice structures are replaced with gate structures. For example, as described with reference to FIGS. 10A, 10B, 11A, and 11B, polysilicon structures 312, thermal oxide layers 323, and sacrificial layers 313 are replaced with gate structures 112P and 112N. The formation of gate structures 112P and 112N can include removing polysilicon structures 312, and sacrificial layers 313 from the structure of FIGS. 9A and 9B to form gate openings 1012, as shown in FIGS. 10A and 10B, and forming gate structures 112P and 112N in gate openings 1012, as shown in FIGS. 11A and 11B. In some embodiments, the formation of gate structures 112P and 112N can be followed by the formation of S/D contact structures 120P and 120N, as shown in FIGS. 11A and 11B.

The present disclosure provides example structures of low-k (LK) spacer structures (e.g., LK spacer structures 114) in FETs (e.g., finFETs and GAA FETs) to reduce parasitic capacitance in the FETs and provides methods of forming the spacer structures. In some embodiments, a FET (e.g., PFET 102P and NFET 102N) can include gate structures (e.g., gate structures 112P and 112N) surrounding nanostructured channel regions (e.g., nanostructured channel regions 113), S/D regions (e.g., S/D regions 110P and 110N) adjacent to the nanostructured channel regions, and LK spacer structures (e.g., LK spacer structures 114) disposed on sidewalls of the gate structures and on the S/D regions. The LK spacer structures can include an LK inner spacer layer (e.g., LK inner spacer layer 114A) disposed on the sidewalls of the gate structures and an LK outer spacer layer (e.g., LK outer spacer layer 114B) disposed on the inner spacer layer and the S/D regions. In some embodiments, the inner spacer layer can include a higher concentration of carbon atoms than that in the outer spacer layer and the outer spacer layer can include a higher concentration of nitrogen atoms than that in the inner spacer layer. In some embodiments, the inner spacer layer can include a carbon-rich dielectric material with a low concentration or zero concentration of nitrogen atoms and the outer spacer layer can include a dielectric nitride and/or an oxygen-rich dielectric material with a low concentration or zero concentration of carbon atoms. Such compositions of the inner and outer spacer layers can form the inner spacer layer with a dielectric constant lower than that of the outer spacer layer. In addition, such compositions can form the inner and outer spacer layers with low dielectric constants of about 1 to about 4 to reduce or minimize parasitic capacitance between the gate structures and the S/D regions. Reducing the parasitic capacitance can improve the reliability and performance of the FET compared to FETs without the LK spacer structures.

In some embodiments, (i) the inner spacer layer can include SiOₓC_{y} or other suitable dielectric carbide material with a higher concentration of carbon atoms than that in SiOₓC_{y}N_{z}, SiCₓN_{y}, or other suitable dielectric nitride material of the outer spacer layer, and (ii) the inner spacer layer can include carbon-rich SiOₓC_{y} or other suitable carbon-rich dielectric material with a higher concentration of carbon atoms than that in oxygen-rich SiOₓC_{y}N_{z}, oxygen-rich SiCₓN_{y}, or other suitable oxygen-rich dielectric material of the outer spacer layer.

In some embodiments, the formation of the LK spacer structure can include (i) forming the inner spacer layers on the sidewalls of the gate structure, (ii) forming sacrificial spacer layers (e.g., sacrificial spacer layers 328) on the inner spacer layers, (iii) removing the sacrificial spacer layers after forming the S/D regions, and (iv) forming the outer spacer layers on the inner spacer layers and the S/D regions. The use of sacrificial spacer layers can prevent the formation of defects on the inner and outer spacer layers. The defects can be in the form of nodules (e.g., nodules 332 and 532) of S/D material formed on the sacrificial spacer layers during the epitaxial growth process of S/D regions. The removal of the sacrificial spacer layers after the formation of the S/D regions can remove these defects and the subsequently-formed outer spacer layers can be formed free of nodular defects. As a result, the uniformity of layers formed on the outer spacer layers are improved with the use of the sacrificial spacer layers.

In some embodiments, a method includes forming a polysilicon structure on a substrate, depositing a first spacer layer on the polysilicon structure, depositing a second spacer layer on the first spacer layer, forming a S/D region on the substrate, removing the second spacer layer, depositing a third spacer layer on the first spacer layer and on the S/D region, depositing an ESL on the third spacer layer, depositing an ILD layer on the etch stop layer, and replacing the polysilicon structure with a gate structure surrounding the nanostructured layer.

In some embodiments, a method includes forming a polysilicon structure on a nanostructured layer on a substrate, depositing an inner spacer layer with a first dielectric constant on the polysilicon structure, depositing a sacrificial spacer layer on the inner spacer layer, forming a S/D region on the substrate, removing the sacrificial spacer layer, depositing, on the inner spacer layer and on the S/D region, an outer spacer layer with a second dielectric constant higher than the first dielectric constant, and replacing the polysilicon structure with a gate structure.

In some embodiments, a semiconductor device includes a substrate, a nanostructured channel region disposed on the substrate, a gate structure surrounding the nanostructured channel region, a S/D region disposed adjacent to the nanostructured channel region, and a spacer structure. The spacer structure includes an inner spacer layer disposed on a sidewall of the gate structure, and an outer spacer layer disposed on the inner spacer layer and on a sidewall and top surface of the S/D region. The semiconductor device further includes a contact structure disposed in the S/D region and the outer spacer layer.

The foregoing disclosure outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
forming a polysilicon structure on a substrate;
depositing a spacer layer on the polysilicon structure;
depositing a sacrificial spacer layer on the spacer layer;
forming a source/drain (S/D) region on the substrate;
removing the sacrificial spacer layer;
performing a doping process on the spacer layer; and
replacing the polysilicon structure with a gate structure.

2. The method of claim 1, wherein depositing the spacer layer comprises depositing a layer of dielectric material comprising a concentration of carbon atoms higher than a concentration of nitrogen atoms.

3. The method of claim 1, wherein depositing the spacer layer comprises depositing a layer of carbon-rich dielectric material.

4. The method of claim 1, wherein removing the sacrificial spacer layer comprises oxidizing the sacrificial spacer layer.

5. The method of claim 4, wherein removing the sacrificial spacer layer comprises performing an etch process on the oxidized sacrificial spacer layer.

6. The method of claim 1, further comprising performing an annealing process on the spacer layer after performing the doping process.

7. The method of claim 1, further comprising depositing another spacer layer on the spacer layer after performing the doping process.

8. The method of claim 7, wherein depositing the other spacer layer comprises depositing a layer of dielectric material comprising a concentration of nitrogen atoms higher than a concentration of carbon atoms.

9. The method of claim 7, wherein depositing the other spacer layer comprises depositing a layer of dielectric material comprising a concentration of nitrogen atoms higher than a concentration of nitrogen atoms in the spacer layer.

10. The method of claim 7, wherein depositing the other spacer layer comprises depositing a layer of dielectric material comprising a concentration of carbon atoms lower than a concentration of carbon atoms in the spacer layer.

11. A method, comprising:
forming a polysilicon structure on a nanostructured layer on a substrate;
depositing an inner spacer layer with a first dielectric constant on the polysilicon structure;
depositing a sacrificial spacer layer on the inner spacer layer;
forming a source/drain (S/D) region on the substrate;
removing the sacrificial spacer layer after forming the S/D region;
performing an anneal process on the inner spacer layer; and
replacing the polysilicon structure with a gate structure surrounding the nanostructured layer.

12. The method of claim 11, wherein depositing the inner spacer layer comprises depositing a dielectric material comprising a concentration of carbon atoms higher than a concentration of nitrogen atoms.

13. The method of claim 11, further comprising depositing an outer spacer layer with a second dielectric constant higher than the first dielectric constant and a concentration of nitrogen atoms higher than a concentration of carbon atoms.

14. The method of claim 13, further comprising forming a contact structure in the S/D region through the outer spacer layer.

15. The method of claim 11, wherein removing the sacrificial spacer layer comprises exposing the sacrificial spacer layer to an oxidizing solution.

16. The method of claim 11, further comprising forming an isolation layer between the S/D region and the substrate.

17. A semiconductor device, comprising:
a substrate;
a gate structure disposed on the substrate;
a source/drain (S/D) region disposed adjacent to the gate structure; and
a spacer structure, comprising:
an inner spacer layer comprising a first dielectric constant and disposed on a sidewall of the gate structure; and
an outer spacer layer comprising a second dielectric constant higher than the first dielectric constant and disposed on the inner spacer layer and on a sidewall and a top surface of the S/D region.

18. The semiconductor device of claim 17, wherein the inner spacer layer comprises a doped dielectric layer, and
wherein the outer spacer layer comprises an undoped dielectric layer.

19. The semiconductor device of claim 17, wherein the inner spacer layer comprises fluorine dopants.

20. The semiconductor device of claim 17, wherein a first portion of the outer spacer layer disposed on the inner spacer layer comprises a greater thickness than that of a second portion of the outer spacer layer disposed on the top surface of the S/D region.
